(19) United States
(12) Patent Application Publication
(10) Pub. No.: US 2009/0127686 A1
(43) Pub. Date: May 21, 2009

(54) Stacking die package structure for semiconductor devices and method of the same

(75) Inventors: Wen-Kun Yang, Hsin-Chu City (TW); Chi-Yu Wang, Kaohsiung City (TW); Hsien-Wen Hsu, Lujhou City (TW)

Correspondence Address: BIRCH STEWART KOLASCH & BIRCH, PO BOX 747, FALLS CHURCH, VA, 22040-0747, US

(73) Assignee: Advanced Chip Engineering Technology Inc.

(21) Appl. No.: 11/984,781

(22) Filed: Nov. 21, 2007

(51) Int. Cl. H01L 23/488; H01L 21/58

(52) U.S. Cl. 257/686; 438/108; 257/E23.023; 257/E21.505

(57) ABSTRACT

The present invention disclosed a first multi-die package structure for semiconductor devices, the structure comprises a substrate having die receiving window and inter-connecting through holes formed therein; a first level semiconductor die formed under a second level semiconductor die by back-to-back scheme and within the die receiving window, wherein the first multi-die package includes first level contact pads formed under the first level semiconductor die having a first level build up layer formed there-under to couple to a first bonding pads of the first level semiconductor die; a second level contact pads formed on the second level semiconductor die having a second level build up layer formed thereon to couple to second bonding pads of the second level semiconductor die; and conductive bumps formed under the first level build up layer.

### FIELD OF THE INVENTION

This invention relates to a semiconductor package, and more particularly to a stacking die package for semiconductor devices.

### DESCRIPTION OF THE PRIOR ART

Integrated circuit (IC) dice or “chips” are small, generally rectangular IC devices cut from a semiconductor wafer, such as a silicon wafer, on which multiple ICs have been fabricated. Traditionally, bare IC dice are packaged to protect them from corrosion by enclosing them in die packages. Such packages work well to protect IC dice, but they can be more bulky than desirable for certain multi-chip applications requiring compact die packaging. Improvements in IC packages are driven by industry demands for increased thermal and electrical performance and decreased size and cost of manufacture. In the field of semiconductor devices, the device density is increased and the device dimension is reduced, continuously. The demand for the packaging or interconnecting techniques in such high density devices is also increased to fit the situation mentioned above. The formation of the solder bumps may be carried out by using a solder composite material. Flip-chip technology is well known in the art for electrically connecting a die to a mounting substrate such as a printed wiring board. The function of chip package includes power distribution, signal distribution, heat dissipation, protection and support . . . and so on. As a semiconductor become more complicated, the traditional package technique, for example lead frame package, flex package, rigid package technique, can't meet the demand of producing smaller chip with high density elements on the chip. In general, array packaging such as Ball Grid Array (BGA) packages provide a high density of interconnects relative to the surface area of the package. Typical BGA packages include a convoluted signal path, giving rise to high impedance and an inefficient thermal path which results in poor thermal dissipation performance. With increasing package density, the spreading of heat generated by the device is increasingly important. In order to meet packaging requirements for newer generations of electronic products, efforts have been expended to create reliable, cost-effective, small, and high-performance packages. Such requirements are, for example, reductions in electrical signal propagation delays, reductions in overall component area, and broader latitude in input/output (I/O) connection pad placement.

Recently, integrated circuit (chip) packaging technology is becoming a limiting factor for the development in packaged integrated circuits of higher performance. Due to the assembly package in miniature, MCM (multi-chips module) package is commonly used in the assembly package and electronic devices. Usually, the MCM package mainly comprises at least two chips encapsulated therein so as to upgrade the electrical performance of package.

U.S. Patent Publish No. 20040070083 disclosed a multi-chip package as shown in FIG. 6. The A stacked flip chip package is disclosed comprising two chip carriers, each of which includes at least a chip and a plurality of solder bumps formed on the active surface of the chip used to electrically connect the chip to the chip carrier. A first chip carrier is joined “back to back” with a second chip carrier via an insulating adhesive applied on the inactive surface of the first chip mounted on the first chip carrier and the inactive surface of the second chip mounted on the second chip carrier. The two inactive surfaces are bonded together to form a multi-chip module. Both the topmost surface and the lowermost surface of the multi-chip module are capable of being electrically connected with other components, thereby eliminating one of the obstacles associated with vertically stacking chips in flip-chip technology and further varying arrangement flexibility of the chips in a package.

FIG. 6 is a cross-sectional view of a multi-flip chip semiconductor package of the prior art. The multi-flip chip semiconductor package in this preferred embodiment is almost identical to the foregoing first embodiment, with the only difference being that in this embodiment at least two multi chip modules described in the foregoing embodiments are stacked vertically. Since the multi-chip module 2′ is formed by joining the first chip carrier 20 to the second chip carrier 23 in a back-to-back manner, both the topmost surface 230′ and the lowermost surface 200′ of the multi-chip module 2′ are capable of forming a plurality of bond pads 203′ and 233′ thereon which in turn can be electrically connected with other multi-chip modules or other components. As shown in the drawing, this multi-chip module of the art further comprises an upper multi-chip module 2′ and a lower multi-chip module 2″ in which the first chip carrier 20′ of the upper multi-chip module 2′ is electrically connected to the second chip carrier 23″ of the lower multi-chip module 2″ via a plurality of solder bumps 28, thus, allowing the chips encapsulated inside the multi-chip module 2′ to be electrically connected to the first substrate 20″ of the lower multi-chip module 2″, which is then electrically connected to external components via a plurality of solder balls 29″ mounted on the back of the first chip carrier 20″.

It is because that the conventional designs include too many stacked dielectric layers and sealed compound, and the thermal dissipation is very poor, thereby decreasing the performance of the devices. The mechanical property of the dielectric layers is not “elastic/softness”, it therefore leads to the CTE mismatching issue; It lacks of the stress releasing buffer layers contained therein. Therefore, the scheme is not reliable during thermal cycle and the operation of the package. Further, It is same die size scheme, the inter core does not include fiber glass and the inter-connecting through hole process is too complicated.

Therefore, the present invention provides a package on package structure to overcome the aforementioned problem and also provide the better device performance.

### SUMMARY OF THE INVENTION

An object of the present invention is to provide a semiconductor device package (chip assembly) with a chip and a conductive trace that provides a low cost, high performance and high reliability package.

A further object of the present invention is to provide a stacking structure for semiconductor devices.

Another object of the present invention is to provide a convenient, cost-effective method for manufacturing a semiconductor multi-die package.

In one aspect, a first multi-die package structure for semiconductor devices, comprises a substrate having die receiving window and inter-connecting through holes formed therein; a first level semiconductor die formed under a second level semiconductor die by back-by-back scheme and within the die receiving window, wherein the first multi-die package includes first level contact pads formed under the first level semiconductor die having a first level build up layer formed there-under to couple to a first bonding pads of the first level semiconductor die; a second level contact pads formed on the second level semiconductor die having a second level build up layer formed thereon to couple to second bonding pads of the second level semiconductor die; and conductive bumps formed under the first level build up layer for coupling to the first level contact pads.

A method of forming a multi-die package structure comprises: applying a second die (wafer form) with active surface on a second tape and applying a back side of a first die (wafer form) on a first tape (the tape with die attached material—DAF: die attached film). Then, the first die (with DAF) is picking and placing on the back side of the second die having an alignment pattern for fine alignment during placement. Then, the die attached material is cured. Preferably, the DAF includes the composition of (i) epoxy resin, phenol resin; (2) acrylic rubber; (3) Si filler. The function of epoxy resin, phenol resin is heat resistance and has the properties of low CTE. The function of acrylic rubber is stress reduction and the function of Si filler is cohesion strength. Therefore, the DAF may have the high reflow resistance, TCT resistance and the increase of adhesion strength. The dimension of the Si particles in Si filer is less than 1 micron-meter. The weight percentage of Si filler is less than 10 percentage.

The first die and second die are picked from sawed wafer to place onto a die placement tool and sucking the active surface of the second die onto the die placement tool. The next step is to align a substrate having die receiving window to the adhered first die and second die and adhered on the die placement tool by glue pattern, wherein the substrate includes inter-connecting through holes; A core paste (die attached) material is formed into the gap between the edge of the first die, the second die and the sidewall of the die receiving window; A panel wafer is attached on the die placement tool. Next is to coat a first lower dielectric layer on the active surface of the first die and exposing first bonding pads and first contact pads (connecting to inter-connecting through holes) of the substrate. A lower RDL is formed to couple to the first bonding pads; A second lower dielectric layer is formed on the lower RDL and exposing first contact pads to form a first UBM structure; A glue pattern is released to separate the panel wafer from the die replacement tool, and followed by cleaning the active surface of the second die; A first upper dielectric layer is formed and expose a second bonding pads of the second die and second contact pads of the substrate; An upper RDL is formed to coupled to the second bonding pads, and a second upper dielectric layer is formed to expose the second contact pads to form a second UBM structure.

The method further comprises a step of forming an isolation base with adhesion material over the upper RDL and/or the second upper dielectric layer (the second upper dielectric layer maybe replaced by the adhesion material), followed by curing the isolation base. A carrier is used to support the panel after releasing from the die placement tool and protect the lower RDL before forming the first upper dielectric layer. It further includes step of releasing the carrier from the panel after forming the first upper build up layer, followed by cleaning the surface of lower side, and performing ball placement to form conductive balls. A second panel is aligning and placing onto the first panel to let ball array contacts with flux of UBM, followed by re-flowing to form interconnection for package on package stacking structure.

### BRIEF DESCRIPTION OF THE DRAWINGS

FIG. 1 is cross-sectional views showing a semiconductor chip assembly in accordance with present invention.

FIG. 2 is cross-sectional views showing a semiconductor chip assembly in accordance with embodiment of the present invention.

FIG. 3 illustrates a cross section view showing semiconductor chip assembly in accordance with embodiment of the present invention.

FIG. 4 illustrates a cross section view showing semiconductor chip assembly in accordance with embodiment of the present invention.

FIG. 5 illustrates a cross section view showing semiconductor chip assembly in accordance with further embodiment of the present invention.

FIG. 6 illustrates a cross section view showing semiconductor chip assembly in accordance with prior art.

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying Claims.

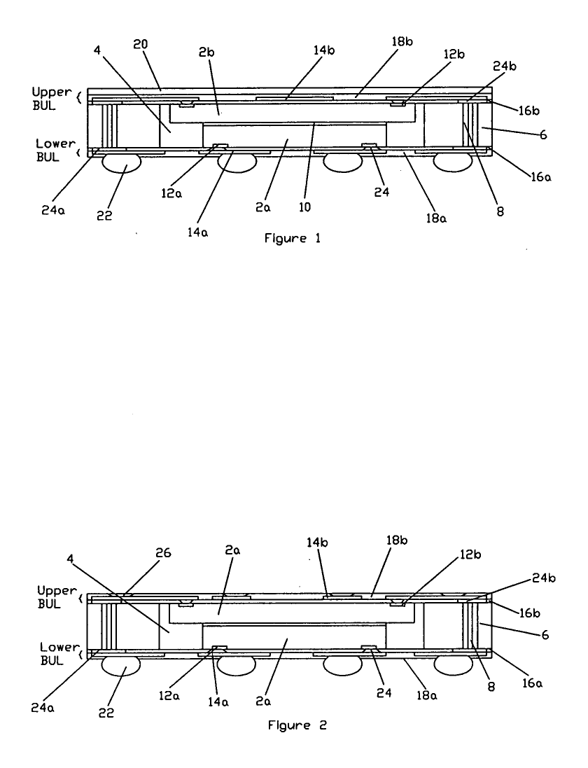

The present invention discloses a semiconductor device multi-package structure. The present invention provides a semiconductor chip assembly which includes multiple chips as shown in FIGS. 1-5. The major components and the structure of each individual package are almost identical. The embodiment will be described as follows.

The package includes at least dual chips 2a, 2b which are surrounded by core paste material 4 embedded in a core substrate 6 having interconnecting through-hole 8 penetrating through the core substrate 6. Surrounding core paste material 4 is formed between the sidewall of the chips 2a, 2b. The core paste material 4 may act as a buffer layer to release the thermal stress. It should be noted that that the chips are stacked with the configuration of bask-to-back scheme by die attachment material 10, for example, so called “DAF-B stage tape”. In one case, the lower chip 2a is up-side down formed under the chip 2b. The up-side refers to the active surface having bonding pads. The die adhesive material 10 is attached under the chip 2b. It could have the elastic properties to absorb the stress generated by thermal.

The interconnecting through-hole 8 is coupled to the bonding pads 12b of the chip 2b by redistribution layer (RDL) 14b. An upper build-up layer (BUL) is formed over the chip 2b, the core paste material 4 and to form RDL 14b. A lower BUL is formed on the lower surface as well. The upper BUL includes a first dielectric layer 16b formed on the upper chip 2b and the upper (first) RDL 14b formed on the first dielectric layer 16b. A second dielectric layer 18b is covered on the upper (first) RDL 14b. A top isolating base 20 is optionally formed on the second dielectric layer 18 for laser marking. Similarly, the lower build-up layer (BUL) is formed on the chip 2a, the core paste material 4 and to form RDL 14a. The lower BUL includes a third dielectric layer 16a formed on the lower chip 2a and the lower (second) RDL 14a formed on the third dielectric layer 16a. A forth dielectric layer 18a is covered on the lower (second) RDL 14a. The forth dielectric layer 18a has openings to expose a portion of the RDL 14a and conductive bumps 22 are formed over the openings and connected to the RDL 14a (the UBM structure, not shown in the drawing).

A first contact pad (UBM, not shown) 24b and a second contact pad 24a are respectively connected two terminals of the interconnecting through-hole 8. The first contact pads 24b are formed under the upper RDL 14b and aligned to the interconnecting through-holes 8, respectively. The second contact pads 24a are formed upper of the lower RDL 14a and aligned to the interconnecting through-holes 8, respectively. The contact metal pads 24a, 24b could be Cu/Ni/Au pads or other metal pads.

The isolation base 20 is stacked over the upper build-up layer. For example, the isolation base 20 is composed of epoxy FR4/FR5, PI, BT, preferably, it is PI or BT base with fiber glass formed therein. The first or second RDL is formed by an electroplating, plating or etching method. The copper (and/or nickel) electroplating operation continues until the copper layer has the desired thickness. The upper RDL extend out of the area for receiving chip. It refers to fan-out scheme. The core paste materials 4 encapsulated the die 2a, 2b. It can be formed by resin, compound, silicon rubber, PI, BT or organic material.

The second embodiment of the present invention is similar to the last one embodiment as shown in FIG. 2. The embodiment omits the isolation base and includes top contact pads formed within the second dielectric layer 18b, it includes the UBM structure.

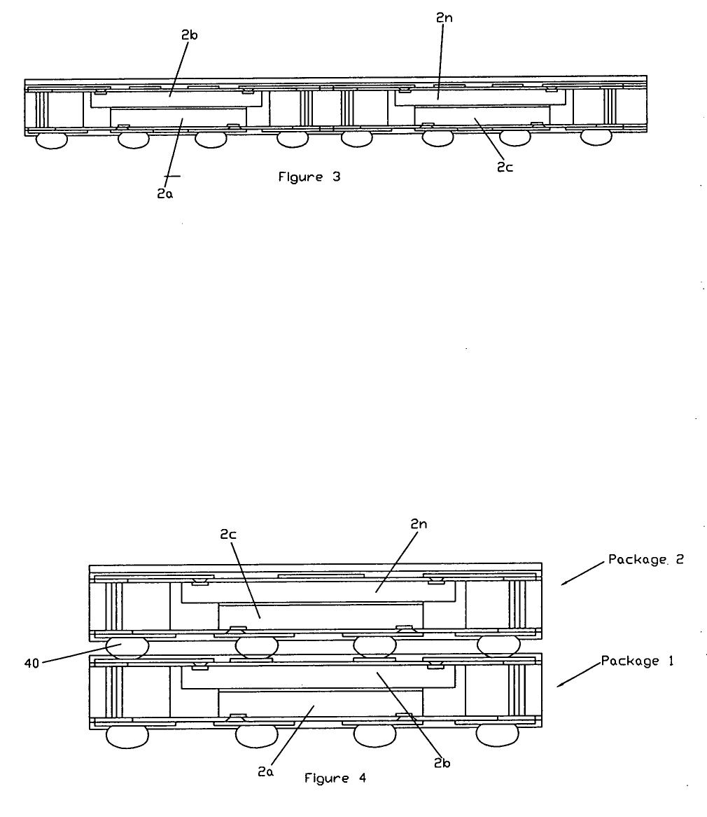

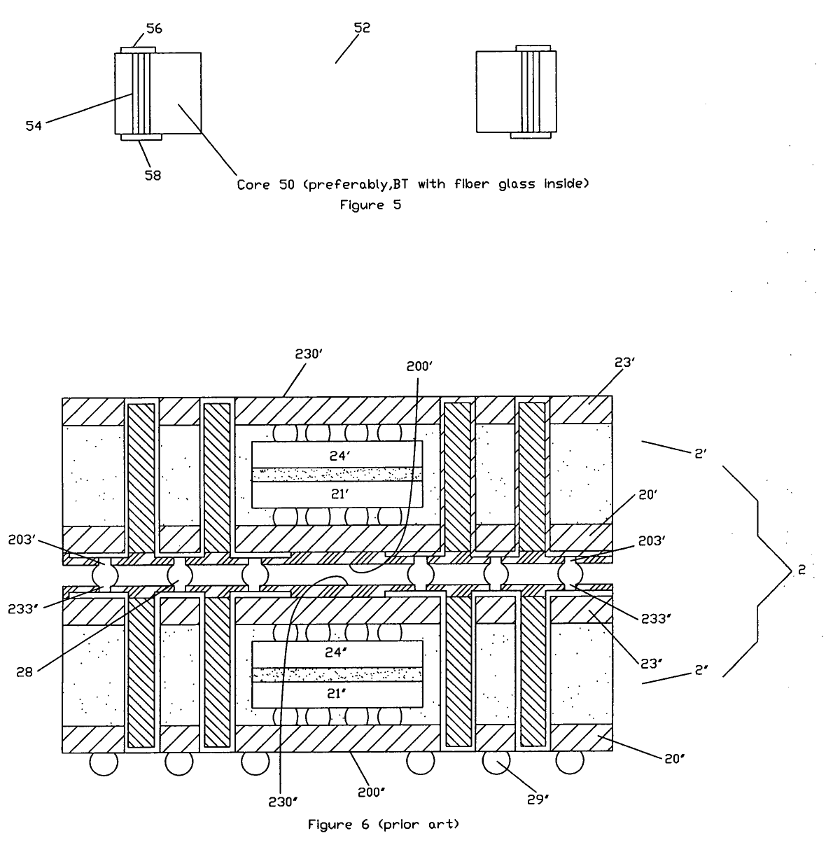

Alternatively, the embodiment includes two units of the first embodiment and configured by side-by-side scheme as shown in FIG. 3. It includes die 2a, 2b, 2c and 2n.

Alternatively, the die may be different type from others. It could be memory, ACIS, MCU, RF, Analog, and/or passive compounds etc.

Please refer to FIG. 4, it is constructed by at least two units of the first embodiment, the solder (conductive) bumps 40 of the upper level package coupled to the upper RDL of the lower level package. Alternative, the isolation base is formed on the upper level unit.

The die size is decreased from top level to low level, subsequently. The smaller the chip is, the larger the core paste material is. Under the scheme, the core area of the lower die is the largest. It may strength the mechanical support to carry higher level package.

FIG. 5 illustrates the substrate 50 of the present invention. The substrate 50 includes pre-formed die receiving window (opening) 52 and the connecting through-holes 54 are pre-formed within the substrate 50. Upper and lower contact pads 56, 58 are respectively formed two terminals of the connecting through-holes 54.

The die on die is configured with stacking structure. Panel stacking process can be applied by using soldering metal inter-connecting or by drilling through hole, followed by forming conductive interconnecting. The panel level final testing is adaptable for each panel structure, and the panel level packaging process with fan-out structure can be applied for each panel. Repairable structure is offered and it maybe repaired by de-soldering process. The passive components are stacking on top by SMT process. Side-by-side scheme is possible. The present invention offers better reliability due to same CTE (using the same core materials—BT or FR5) in each package and PCB. The buffer layer and the dielectric layers have the elastic properties to release the thermal stress between silicon and PCB substrate/BT. The scheme is suitable for KGD (known good die) process (picking up the good die processing). The present invention is “green package” for environment protection.

A method of forming a multi-die package structure comprises: applying a second die (wafer form) with active surface on a second tape and applying a back side of a first die on a first tape (the tape with DAF structure—die attached film). Then, the first die (with DAF under the back side of first die) is picking and placing on the back side of the second die having an alignment pattern for fine alignment during placement. Then, the die attached material is cured to firm the die to die (back to back) so as to attach the both die for each other.

The first die and second die (attached together by back-by-back) are picked from sawed wafer (form the second die wafer) to place onto a die placement tool (with alignment pattern and patterned glues) and sucking the active surface of the second die onto the die placement tool. The next step is to align a substrate having die receiving window to the adhered first die and second die and adhered on the die placement tool by glue pattern, wherein the substrate includes inter-connecting through holes; A core paste (die attached) material is formed into the gap between the edge of the first die, the second die and the sidewall of the die receiving window; Next is to coat a first lower dielectric layer on the active surface of the first die and exposing first bonding pads and first contact pads of the substrate. A lower RDL is formed to couple to the first bonding pads; A second lower dielectric layer is formed on the lower RDL and exposing first solder contact pads to form a first UBM structure; A glue pattern is released to allow the panel wafer separating from the die replacement tool, and followed by cleaning the active surface of the second die; A first upper dielectric layer is formed and expose a second bonding pads of the second die and second contact pads of the substrate; An upper RDL is formed to coupled to the second bonding pads, and a second upper dielectric layer is formed to expose the second solder contact pads to form a second UBM structure.

An another method of forming a die stack die structure comprises preparing the first die placement tooling with alignment pattern and pattern glues (it may be thermal or UV tape), lapping and sawing the first wafer (becomes die), and picking and placing the first die (good die) with active surface, the active surface is placed and stuck on the pattern glue of die placement tools (note—the back side of first die has attached the DAF die attached material tape). The next step is to prepare the second die placement tooling with alignment pattern and pattern glues, lapping and sawing the second wafer (becomes die), and picking and placing the second die (good die) with active surface and the active surface is placed and stuck on the pattern glue of die placement tools. Then, the next is to reverse (upside down) the first die placement tools (has first dice be placed) to align and bonding on the second die placement tool with special alignment target (now, the back side of first die is attached to the back side of second die), then, curing the DAF die attached materials. Next step is to release the pattern glues of first die placement tools (it maybe released by heat or UV light). The following steps are similar to the previous step—placement the substrate, filling the core paste material, curing step, forming the lower BUL and forming upper BUL etc.

The method further comprises a step of forming an isolation base with adhesion material over the upper RDL and/or the second upper dielectric layer (the second upper dielectric layer maybe replaced by adhesion material under the isolating base), followed by curing the isolation base. A carrier is used to support the panel from once be released from the die placement tool and protect the lower RDL before forming the first upper dielectric layer. It further includes step of releasing the carrier from the panel after formed the first upper build up layer, followed by cleaning the surface of lower side, and performing ball placement to form the conductive ball under the UBM. A second panel is aligning and placing onto the first panel to let ball array contacts with flux of UBM, followed by re-flowing to form interconnection for package on package structure.

The method further comprises a step of sawing panels from scribe lines to separate the package. The RDL (within build up layers) is formed by sputtered seed metal, PR to form RDL pattern, E-plated Cu/Ni/Au (or Cu/Au), strip PR, and wet etching seed metal to form the RDL trace.

The present invention provides better reliability in TCT (temperature cycling test), drop test, ball shear test due to the properties of the core substrate materials, isolating base and the CTE of core substrate materials, isolating base (the preferred materials for the isolating base and substrate include PI or BT) is matching with CTE of print circuit board (PCB), furthermore, the core paste material and build up layers with elastic/elongation properties can absorb the thermal mechanical stress between silicon chip and core substrate during temperature cycling.

Since the isolating base has fiber glass inside (preferably), the strength of isolating base (BT/FR5/FR4/PI . . . ) is great than the top dielectric layer, so, it can prevent the build up layers from being damaged during the external force, especially in package edge area. It is easy to replace the solder balls/bumps during rework process: the normal rework procedure of solder balls will not damage the top surface of package due to has isolating base.

Although preferred embodiments of the present invention has been described, it will be understood by those skilled in the art that the present invention should not be limited to the described preferred embodiment. Rather, various changes and modifications can be made within the spirit and scope of the present invention, as defined by the following Claims.

What is claimed is:

1. A first multi-die package structure for semiconductor devices, comprising:
a substrate having die receiving window and inter-connecting through holes formed therein;
a first level semiconductor die formed under a second level semiconductor die by back-to-back scheme and within said die receiving window, wherein said first multi-die package includes first level contact pads formed under said first level semiconductor die having a first level build up layer formed there-under to couple to a first bonding pads of said first level semiconductor die; a second level contact pads formed on said second level semiconductor die having a second level build up layer formed thereon to couple to second bonding pads of said second level semiconductor die; and
conductive bumps formed under said first level build up layer for coupling to said first level contact pads.

2. The structure of claim 1, wherein said first level build up layer includes a sandwich structure having dielectric/RDL/dielectric.

3. The structure of claim 2, further comprising UBM structure in said first level build up layer for coupling said RDL.

4. The structure of claim 1, wherein said second level build up layer includes a sandwich structure having dielectric/RDL/dielectric.

5. The structure of claim 4, further comprising UBM structure in said second level build up layer for coupling said RDL.

6. The structure of claim 1, further comprising adhesion materials attached between said first and second level semiconductor dice.

7. The structure of claim 1, wherein said first level build up layer coupled to said second build up layer through interconnecting through holes.

8. The structure of claim 1, wherein said first level die is adhered with said second level die by an adhesive material having elastic properties.

9. The structure of claim 8, wherein said adhesive material includes silicon rubber, rubber resin, epoxy resin, polymer resin or the composition thereof.

10. The structure of claim 1, further comprising an isolation base formed over said second level package.

11. The structure of claim 10, wherein said isolation base is formed of epoxy, FR4, FR5, PI, PCB, BT or organic material.

12. The structure of claim 11, wherein said isolation base includes glass fiber contained therein.

13. The structure of claim 1, further comprising core paste material formed adjacent to said first and second level semiconductor dice.

14. The structure of claim 1, further comprising a second multi-die structure formed adjacent to said first multi-die structure.

15. The structure of claim 1, further comprising a third multi-die structure formed on said first multi-die structure.

16. The structure of claim 15, further comprising further conductive bumps connected between said first and said third multi-die structures.

17. A method of forming a multi-die package structure for semiconductor devices, comprising:
applying a second die with active surface on a first tape;
applying a back side of a first die on a second tape;
picking and placing said first die on the back side of said second die having an alignment pattern for fine alignment during placement;
picking said adhered first die and second die from sawed wafer to place onto a die placement tool and sucking said active surface of said second die onto said die placement tool;
aligning a substrate having die receiving window to said adhered first die and second die and adhered on said die placement tool by glue pattern, wherein said substrate includes inter-connecting through holes;
forming core paste material into the gap between the edge of said first die, said second die and the sidewall of said die receiving window;
coating a first lower dielectric layer on the active surface of said first die and exposing first bonding pads and first contact pads of said substrate;
forming a lower RDL to couple to said first bonding pads;
forming a second lower dielectric layer on said lower RDL and exposing first solder contact pads to form a first UBM structure;
releasing glue pattern to separate a panel from said die replacement tool, and followed by cleaning said active surface of said second die;
forming a first upper dielectric layer and expose a second bonding pads of said second die and second contact pads of said substrate;
forming a upper RDL to coupled to said second bonding pads;
forming a second upper dielectric layer and to expose said second solder contact pads to form a second UBM structure.

18. The method of claim 17, further comprising a step of forming an isolation base with adhesion material over said upper RDL and/or said second upper dielectric layer, followed by curing said isolation base.

19. The method of claim 17, further comprising forming using a carrier to support said panel from said die placement tool and protect the lower RDL before forming said first upper dielectric layer.

20. The method of claim 19, further comprising releasing said carrier from said panel, followed by cleaning the surface of lower side, and performing ball placement.

21. The method of claim 17, further comprising aligning and placing a second panel onto said first panel to let ball array contacts with flux of UBM, followed by re-flowing to form interconnection.

22. The method of claim 18, wherein said isolation base is formed of epoxy, FR4, FR5, PI, PCB, BT or organic material.

23. The method of claim 22, wherein said isolation base includes glass fiber contained therein.

24. The method of claim 17, further comprising core paste material formed adjacent to said first and second dice.

25. The method of claim 17, wherein said first die and said second die are adhered by adhesive material that includes silicon rubber, rubber resin, epoxy resin, polymer resin or the composition thereof.
